(19) United States
(12) Patent Application Publication
(10) Pub. No.: US 2024/0331967 A1
(43) Pub. Date: Oct. 3, 2024

(54) LIQUID METAL ION SOURCE DEVICE FOR USING BISMUTH AND ALLOY OF BISMUTH

(71) Applicant: KOREA BASIC SCIENCE INSTITUTE, Daejeon (KR)

(72) Inventors: Myoung Choul Choi, Chungcheongbuk-do (KR); Woo Jun Byeon, Seoul (KR); Byeong Jun Cha, Chungcheongbuk-do (KR)

(73) Assignee: KOREA BASIC SCIENCE INSTITUTE, Daejeon (KR)

(21) Appl. No.: 18/407,388

(22) Filed: Jan. 8, 2024

(30) Foreign Application Priority Data
Mar. 30, 2023 (KR) 10-2023-0042046

(51) Int. Cl. H01J 37/08

(52) U.S. Cl. CPC H01J 37/08; H01J 2237/032; H01J 2237/0805; H01J 2237/208

(57) ABSTRACT

A liquid metal ion source device for using bismuth and an alloy of the bismuth is provided. The liquid metal ion source device includes a base formed of an electrically insulating material, two electrodes connected to the base and configured to supply current, a needle mounted on the base and configured to pass through the base, a filament including a pair of connection rods connected to the two electrodes, respectively, a pair of support rods formed to be extended from the pair of connection rods, respectively, and provided in a direction away from the base and towards the needle, and a filament head connecting the pair of support rods to one another and having a shape curved toward the base, and a reservoir configured to accommodate at least a portion of the filament head inside the reservoir and store a liquid metal.

### CROSS-REFERENCE TO RELATED APPLICATION

This application claims the benefit of Korean Patent Application No. 10-2023-0042046, filed on Mar. 30, 2023, in the Korean Intellectual Property Office, the entire disclosure of which is incorporated herein by reference for all purposes.

### BACKGROUND

### 1. Field of the Invention

One or more embodiments relate to a liquid metal ion source device for using bismuth and an alloy of the bismuth.

### 2. Description of the Related Art

A liquid metal ion source is the core of a focused ion beam system used for sub-micrometer microfabrication, integrated circuit modification, surface analysis of various samples, thin film sample production for transmission electron microscopy (TEM), etc. The liquid metal ion source is characterized by high current stability, high current density, and low energy spread and defects compared to other ion sources. Recently, the focused ion beam system using the liquid metal ion source is expanding the applicability to various fields, including the development of next-generation semiconductor devices.

### SUMMARY

According to an aspect, there is provided a liquid metal ion source device for using bismuth and an alloy of the bismuth, the liquid metal ion source device including a base formed of an electrically insulating material, two electrodes connected to the base and configured to supply current, a needle mounted on the base and configured to pass through the base, a filament including a pair of connection rods connected to the two electrodes, respectively, a pair of support rods formed to be extended from the pair of connection rods, respectively, and provided in a direction away from the base and towards the needle, and a filament head connecting the pair of support rods to one another and having a shape curved toward the base, and a reservoir configured to accommodate at least a portion of the filament head inside the reservoir and store a liquid metal.

The needle may include a needle body configured to penetrate an inside of the reservoir, and a needle tip formed to be extended from the needle body and having a conical shape with a radius that decreases in a direction away from the base.

The needle body may be connected to the base and the two electrodes are provided on opposite sides with respect to the needle body.

The needle body may be connected to the filament head.

The reservoir may be provided to be spaced apart from the filament head.

The connection rods, the support rods, and the filament head may have the same thickness.

The filament head may have a shape convexly curved toward the base.

The filament head may include both end portions connected to the pair of support rods, and a central portion provided between the both end portions and provided closer to the base than the both end portions.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a perspective view illustrating a liquid metal ion source device according to an embodiment;

FIG. 2 is a front view illustrating a needle, a filament, and a reservoir, according to an embodiment;

FIG. 3 is a diagram illustrating a Taylor cone according to an embodiment;

FIGS. 4A to 4D are diagrams illustrating liquid metal ion source devices in which filament heads accommodated in a reservoir have different lengths, according to an embodiment;

FIG. 5 is a graph illustrating emission current of an ion source versus time in the different liquid metal ion source devices of FIGS. 4A to 4D, according to an embodiment; and

FIG. 6 is a graph illustrating the emission current of the ion source versus a length ratio between the reservoir and the filament heads accommodated in the reservoir in the different liquid metal ion source devices of FIGS. 4A to 4D, according to an embodiment.

### DETAILED DESCRIPTION

The following detailed structural or functional description is provided as an example only and various alterations and modifications may be made to the embodiments. Accordingly, the embodiments are not construed as being limited to the disclosure and should be understood to include all changes, equivalents, and replacements within the technical scope of the disclosure.

Although terms of “first,” “second,” and the like are used to explain various components, the components are not limited to such terms. These terms are used only to distinguish one component from another component. For example, a first component may be referred to as a second component, and similarly the second component may also be referred to as the first component.

It should be noted that if it is described that one component is “connected”, “coupled”, or “joined” to another component, a third component may be “connected”, “coupled”, and “joined” between the first and second components, although the first component may be directly connected, coupled, or joined to the second component.

As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

The same name may be used to describe an element included in the embodiments described above and an element having a common function. Unless disclosed to the contrary, the description of any one embodiment may be applied to other embodiments, and the specific description of the repeated configuration will be omitted.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

Hereinafter, embodiments will be described in detail with reference to the accompanying drawings. When describing the embodiments with reference to the accompanying drawings, like reference numerals refer to like components and a repeated description related thereto will be omitted.

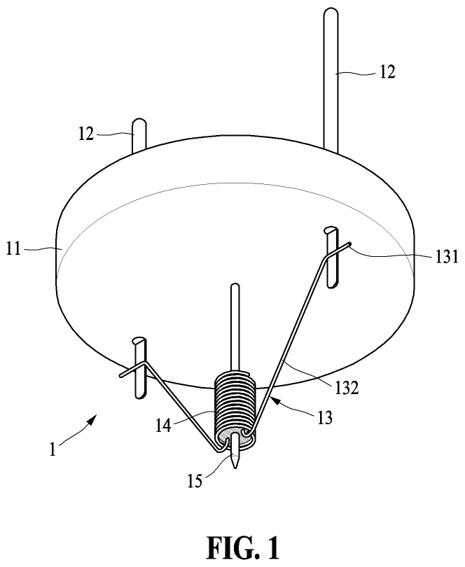

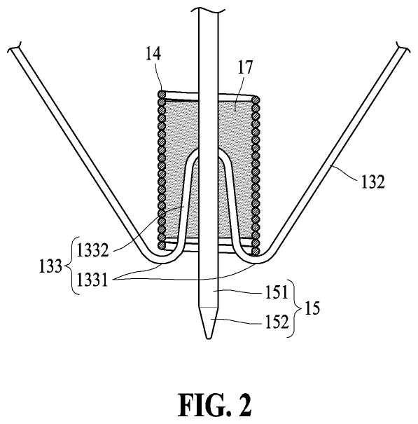

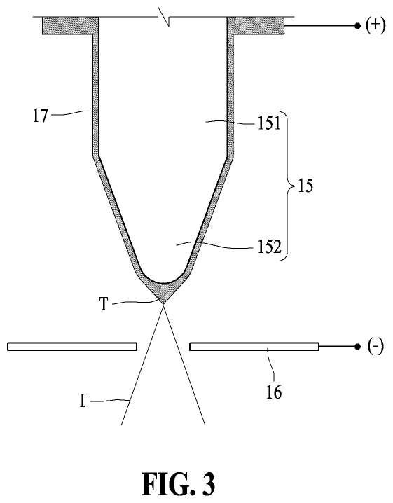

FIG. 1 is a perspective view illustrating a liquid metal ion source device according to an embodiment, FIG. 2 is a front view illustrating a needle, a filament, and a reservoir, according to an embodiment, and FIG. 3 is a diagram illustrating a Taylor cone according to an embodiment.

Referring to FIGS. 1 to 3, according to an embodiment, a liquid metal ion source device 1 (hereinafter, referred to as “the liquid metal ion source device”) for using bismuth and an alloy of the bismuth may form an ion beam I from an ion source. A liquid metal ion source may be used as a type of the ion source. Liquid metal may be in a solid state at room temperature and may melt into a liquid state when heated to a temperature above the melting point. The liquid metal may include gallium (Ga), indium (In), gold (Au), beryllium (Be), silicon (Si), palladium (Pd), aluminum (Al), nickel (Ni), manganese (Mn), an alloy thereof, etc. In the present disclosure, particularly, bismuth or an alloy thereof may be used as a liquid metal 17. The ion beam I may be a mass of ion flow, which may be a group of charged molecules or atoms. The ion beam I may be accelerated by an electric field. The liquid metal ion source device 1 may include a base 11, electrodes 12, a filament 13, a reservoir 14, and a needle 15.

The base 11 may support two electrodes 12 and the needle 15. The base 11 may be formed of an electrically insulating material. For example, the base 11 may be formed of steatite ceramics. Although the base 11 is shown as a circle, it may be noted in advance that the shape of the base 11 is not necessarily limited thereto.

The electrodes 12 are connected to the base 11 and may receive current from a power source. The electrodes 12 may penetrate the base 11. There may be two electrodes 12. Between the two electrodes 12, one electrode may be an anode and the other electrode may be a cathode. The two electrodes 12 may apply current to the filament 13.

The filament 13 may be formed of tungsten. The filament 13 may be heated by the current applied from the electrodes 12. The heated filament 13 may transfer heat to the liquid metal 17 and the needle 15, which are in contact with the filament 13. The liquid metal 17 may be heated in a solid state and melted. The filament 13 may include connection rods 131, support rods 132, and a filament head 133.

The connection rods 131 may be connected to the two electrodes 12, respectively. The connection rods 131 may be provided as a pair. A pair of support rods 132 may be formed to be extended from the pair of connection rods 131, respectively. The pair of support rods 132 may be provided in the direction away from the base 11 and towards the needle 15. The filament head 133 may connect the pair of support rods 132 to one another. The filament head 133 may include both end portions 1331, connected to the pair of support rods 132, and a central portion 1332 provided between the both end portions 1331.

The central portion 1332 may be provided closer to the base 11 than the both end portions 1331. For example, the central portion 1332 may have a shape convexly curved toward the base 11. For example, the central portion 1332 may have a wedge shape of which the end narrows toward the base 11, so that the filament 13 may have a W shape. The filament 13 may have a symmetrical shape with respect to the central portion 1332.

The connection rods 131, the support rods 132, and the filament head 133 may have the same thickness. The connection rods 131, the support rods 132, and the filament head 133 may each be formed integrally from the same material. For example, the filament 13 may be formed by bending a metal wire made of tungsten. Alternatively, the connection rods 131, the support rods 132, and the filament head 133 may each be formed of different materials and may have different thicknesses. At least a portion of the central portion 1332 may be accommodated inside the reservoir 14.

The reservoir 14 may store the liquid metal 17 therein. The reservoir 14 may be formed of tungsten or Kovar. For example, the reservoir 14 may have a cylindrical shape with a hole penetrating in one direction at the center. For example, an inner diameter of the reservoir 14 may be 1 millimeter (mm). The central portion 1332 may be provided in contact with the liquid metal 17, inside the reservoir 14. Since the liquid metal 17 is stored in a solid state inside the reservoir 14 before the filament 13 is heated, the liquid metal 17 may not flow out of the reservoir 14.

The needle 15 may be connected to the base 11 and may penetrate through the inside of the reservoir 14. A portion of the needle 15, positioned inside the reservoir 14, may be in contact with the liquid metal 17. The needle 15 may transfer heat to the liquid metal 17 and may guide flow of the melted liquid metal 17. For example, the needle 15 may be formed of tungsten. The needle 15 may include a needle body 151 and a needle tip 152.

The needle body 151 may be connected to the base 11. The two electrodes 12 may be provided on opposite sides with respect to the needle body 151. For example, the needle 15 may penetrate the central portion of the base 11 and be mounted on the base 11. An influence of external force acting on the needle 15 may be reduced, and an angle formed between the needle 15 and a surface of the base 11 may be maintained constant. The needle 15 may stably guide the liquid metal 17.

Any portion of the needle body 151 may be connected to the central portion 1332. For example, the needle body 151 may be connected to a point closest to the base 11, among portions of the central portion 1332. The liquid metal 17 and the needle 15 may directly receive heat from the central portion 1332. The inside of the reservoir 14 may be maintained at a high temperature, and the liquid metal 17 may be melted. The melted liquid metal 17 may flow along the needle body 151 toward the end portion of the needle tip 152 due to gravity.

The needle tip 152 may be formed to be extended from the needle body 151. For example, the needle tip 152 may be positioned outside the reservoir 14. The needle tip 152 may have a conical shape with a radius that decreases in a direction away from the base 11. At the needle tip 152, a liquid film of the liquid metal 17 may be deformed due to a high electric field, so that electric stress and surface tension may achieve an equilibrium and a Taylor cone T may be formed. As a strong electric field acts on an extraction electrode 16 positioned below the needle body 151 and the needle tip 152, metal ion atoms in a liquid state gathered at the end portion of the needle tip 152 may be attracted to the electric field and may be emitted as ions. Since the above process occurs continuously, the ion beam I may be formed from the liquid metal 17.

When a point where the needle body 151 is connected to the filament 13 is outside the reservoir 14, the filament 13 may transfer heat to the needle 15 from the outside of the reservoir 14 and the liquid metal 17 stored inside the reservoir 14 may melt as the heat is conducted within the needle 15.

When the point where the needle body 151 is connected to the filament 13 is inside the reservoir 14, the filament 13 may simultaneously heat the needle 15 and the liquid metal 17. Compared to the case where the point where the needle body 151 is connected to the filament 13 is outside the reservoir 14, the speed at which the liquid metal 17 is heated may increase and the inside of the reservoir 14 may be maintained at a high temperature. As the liquid metal 17 is smoothly melted in the reservoir 14, the flow of the liquid metal 17 may not interrupted between the reservoir 14 and the needle tip 152 and the Taylor cone T formed at the end portion of the needle tip 152 may maintain a constant shape. The ion beam I may be formed stably without interruption. At the end portion of the needle tip 152, overcurrent due to unstable surface tension and damage to the liquid metal ion source device 1 may be prevented.

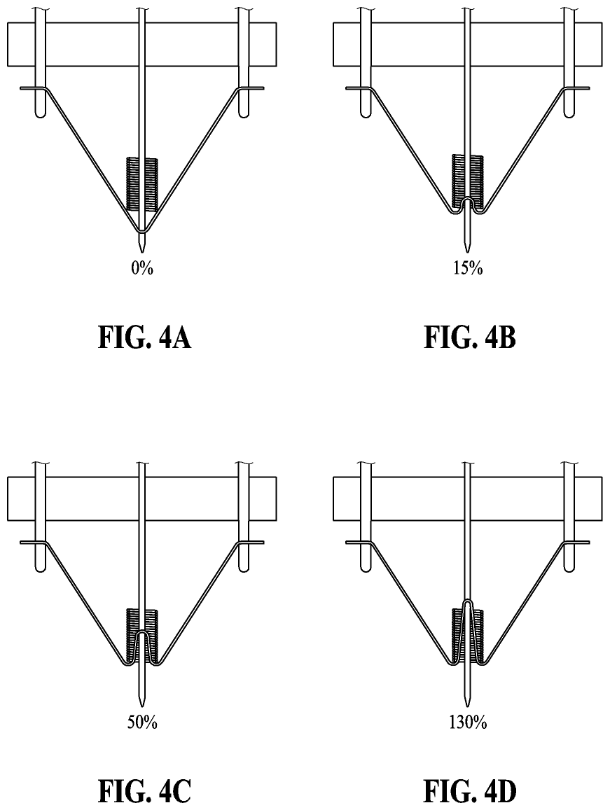

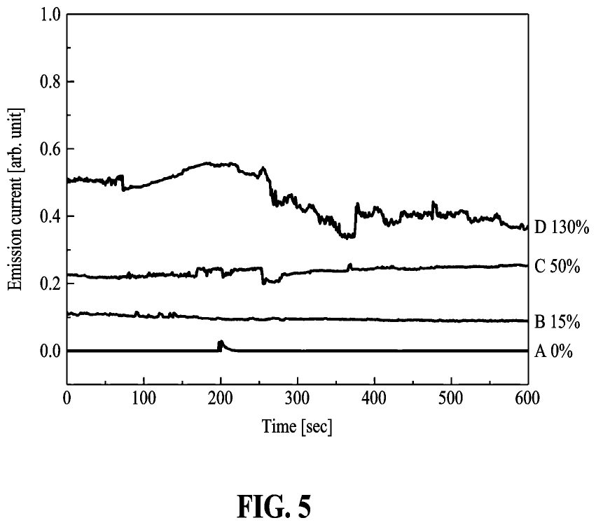

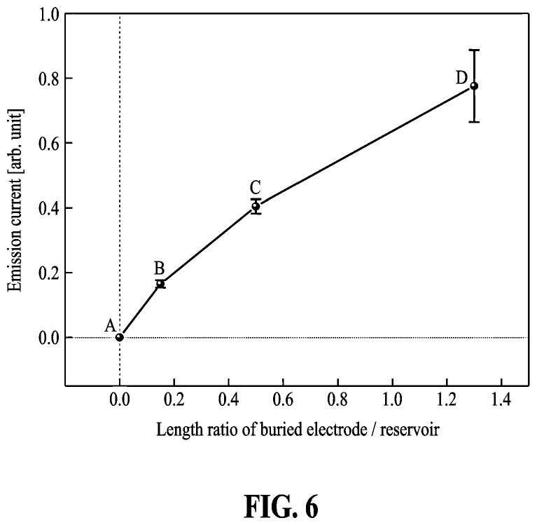

FIGS. 4A to 4D are diagrams illustrating liquid metal ion source devices in which filament heads accommodated in a reservoir have different lengths, according to an embodiment, FIG. 5 is a graph illustrating emission current of an ion source versus time in the different liquid metal ion source devices, according to an embodiment, and FIG. 6 is a graph illustrating the emission current of the ion source versus a length ratio between the reservoir and the filament heads accommodated in the reservoir in the different liquid metal ion source devices, according to an embodiment.

Referring to FIGS. 4A to 6, the ratio of the lengths of the filament heads accommodated in the reservoir with respect to the length of the reservoir may be different. For example, the ratio of the lengths of the filament heads accommodated in the reservoir with respect to the length of the reservoir may be 0%, 15%, 50%, or 130%. However, it may be noted in advance that the lengths of the filament heads accommodated in the reservoir is not necessarily limited thereto. Hereinafter, liquid metal ion source devices are referred to as unit A, unit B, unit C, and unit D, respectively. Unit D may be understood as a portion of the filament head passing through the inside of the reservoir.

In each unit, the emission current of the ion source and the amount of change in the emission current over time may be different. As previously described, a bismuth alloy has been used as the ion source in each unit. In unit A, current may not be emitted from the ion source over time and an ion beam may not be generated from the ion source.

In unit B, unit C, and unit D, current may be emitted from the ion source and an ion beam may be generated from the ion source. As the ratio of the lengths of the filament heads accommodated in the reservoir with respect to the length of the reservoir increases, the current emitted from the ion source may increase, while the amount of change in the current with respect to time may also increase. In each of the different environments, the optimal ratio at which a stable ion beam may be formed may be determined by adjusting the length of the filament head accommodated in the reservoir.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

What is claimed is:

1. A liquid metal ion source device for using bismuth and an alloy of the bismuth, the liquid metal ion source device comprising:
a base formed of an electrically insulating material;
two electrodes connected to the base and configured to supply current;
a needle mounted on the base and configured to pass through the base;
a filament comprising a pair of connection rods connected to the two electrodes, respectively, a pair of support rods formed to be extended from the pair of connection rods, respectively, and provided in a direction away from the base and towards the needle, and a filament head connecting the pair of support rods to one another and having a shape curved toward the base; and
a reservoir configured to accommodate at least a portion of the filament head inside the reservoir and store a liquid metal.

2. The liquid metal ion source device of claim 1, wherein
the needle comprises:
a needle body configured to penetrate an inside of the reservoir; and
a needle tip formed to be extended from the needle body and having a conical shape with a radius that decreases in a direction away from the base.

3. The liquid metal ion source device of claim 2, wherein
the needle body is connected to the base and the two electrodes are provided on opposite sides with respect to the needle body.

4. The liquid metal ion source device of claim 2, wherein
the needle body is connected to the filament head.

5. The liquid metal ion source device of claim 1, wherein
the reservoir is provided to be spaced apart from the filament head.

6. The liquid metal ion source device of claim 1, wherein
the connection rods, the support rods, and the filament head have the same thickness.

7. The liquid metal ion source device of claim 1, wherein
the filament head has a shape convexly curved toward the base.

8. The liquid metal ion source device of claim 1, wherein
the filament head comprises:
both end portions connected to the pair of support rods; and
a central portion provided between the both end portions and provided closer to the base than the both end portions.
